(19) United States
(12) Patent Application Publication
(10) Pub. No.: US 2025/0077166 A1
(43) Pub. Date: Mar. 6, 2025

(54) MULTI-CHANNEL AUDIO INPUT MIXER

(71) Applicant: QUALCOMM Incorporated, San Diego, CA (US)

(72) Inventors: Julio Victor MENDEZ BETHENCOURT, Cambridge (GB); Brendan David TOWNSEND, Cambridge (GB)

(21) Appl. No.: 18/240,896

(22) Filed: Aug. 31, 2023

(51) Int. Cl. G06F 3/16

(52) U.S. Cl. CPC G06F 3/162; G06F 3/165

(57) ABSTRACT

In some aspects, an audio processor may provide, to each digital sample rate converters in a time division multiplexing (TDM) data chain, a set of TDM clocks that include a sample rate clock input and a bit clock input. The digital sample rate converters in each TDM data chain may connect to respective audio ports that each correspond to a stereo channel. The digital sample rate converters in each TDM data chain may receive digital audio inputs via the audio ports. The audio processor may receive, at one or more TDM inputs, a TDM audio stream from each of the one or more TDM data chains, wherein the TDM audio stream mixes the digital audio inputs based on the sample rate clock input and the bit clock input. Numerous other aspects are described.

### FIELD OF THE DISCLOSURE

Aspects of the present disclosure generally relate to audio processing and, for example, to a multi-channel audio input mixer that may convert multiple audio inputs into a time division multiplexed (TDM) audio data stream.

### BACKGROUND

Media systems, including audio/video systems, render (or output) content to permit one or more users to hear and/or view the content. A media system can include a display device (e.g., a television, a projector, or the like) to present video content and/or an audio device (e.g., one or more speakers) to emit audio content. In some cases, the media system can include a soundbar and/or a stereo configuration with multiple speakers. The media system can be controlled to render the content in various ways (e.g., according to various playback settings, audio/video modes, and/or volume settings, among other examples). Various forms of the content can also be available for rendering (e.g., audio can be emitted in different languages and/or video can be presented to include certain metadata, among other examples).

### SUMMARY

In some aspects, a method for mixing multiple audio channels includes connecting an audio processor to one or more time division multiplexing (TDM) data chains that each include a plurality of digital sample rate converters; providing, to the plurality of digital sample rate converters in each TDM data chain, a set of TDM clock inputs that include a sample rate clock input and a bit clock input; connecting the plurality of digital sample rate converters in each TDM data chain to a corresponding plurality of audio ports that each correspond to a stereo channel; receiving, at the plurality of digital sample rate converters in each TDM data chain, a plurality of digital audio inputs via the plurality of audio ports; receiving, at one or more TDM inputs associated with the audio processor, a TDM audio stream from each of the one or more TDM data chains, wherein the TDM audio stream mixes the plurality of digital audio inputs based on the sample rate clock input and the bit clock input; and outputting, by the audio processor, the TDM audio stream.

In some aspects, a device for mixing multiple audio channels includes one or more memories; and one or more processors, coupled to the one or more memories, configured to cause the device to: connect an audio processor to one or more TDM data chains that each include a plurality of digital sample rate converters; provide, to the plurality of digital sample rate converters in each TDM data chain, a set of TDM clock inputs that include a sample rate clock input and a bit clock input; connect the plurality of digital sample rate converters in each TDM data chain to a corresponding plurality of audio ports that each correspond to a stereo channel; receive, at the plurality of digital sample rate converters in each TDM data chain, a plurality of digital audio inputs via the plurality of audio ports; receive, at one or more TDM inputs associated with the audio processor, a TDM audio stream from each of the one or more TDM data chains, wherein the TDM audio stream mixes the plurality of digital audio inputs based on the sample rate clock input and the bit clock input; and output the TDM audio stream.

In some aspects, a non-transitory computer-readable medium storing a set of instructions for wireless communication includes one or more instructions that, when executed by one or more processors of a device, cause the device to: connect an audio processor to one or more TDM data chains that each include a plurality of digital sample rate converters; provide, to the plurality of digital sample rate converters in each TDM data chain, a set of TDM clocks that include a sample rate clock input and a bit clock input; connect the plurality of digital sample rate converters in each TDM data chain to a corresponding plurality of audio ports that each correspond to a stereo channel; receive, at the plurality of digital sample rate converters in each TDM data chain, a plurality of digital audio inputs via the plurality of audio ports; receive, at one or more TDM inputs associated with the audio processor, a TDM audio stream from each of the one or more TDM data chains, wherein the TDM audio stream mixes the plurality of digital audio inputs based on the sample rate clock input and the bit clock input; and output the TDM audio stream.

In some aspects, an apparatus for mixing multiple audio channels comprises means for connecting an audio processor to one or more TDM data chains that each include a plurality of digital sample rate converters; means for providing, to the plurality of digital sample rate converters in each TDM data chain, a set of TDM clocks that include a sample rate clock input and a bit clock input; means for connecting the plurality of digital sample rate converters in each TDM data chain to a corresponding plurality of audio ports that each correspond to a stereo channel; means for receiving, at the plurality of digital sample rate converters in each TDM data chain, a plurality of digital audio inputs via the plurality of audio ports; means for receiving, at one or more TDM inputs associated with the audio processor, a TDM audio stream from each of the one or more TDM data chains, wherein the TDM audio stream mixes the plurality of digital audio inputs based on the sample rate clock input and the bit clock input; and means for outputting the TDM audio stream.

Aspects generally include a method, apparatus, system, computer program product, non-transitory computer-readable medium, user device, user equipment, wireless communication device, and/or processing system as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example environment in which multiple audio inputs may be converted into a time division multiplexed (TDM) audio data stream, in accordance with the present disclosure.

FIG. 2 is a diagram illustrating example components of one or more devices shown in FIG. 1, in accordance with the present disclosure.

FIGS. 3A-3D are diagrams illustrating examples associated with converting multiple audio inputs into a TDM audio data stream, in accordance with the present disclosure.

FIG. 4 is a flowchart of an example process associated with converting multiple audio inputs into a TDM audio data stream, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Inter-integrated circuit (IC) sound, abbreviated I2S or alternatively I²S (and typically pronounced “eye-squared-ess”), is a digital audio protocol that frames n bytes of streamed data packets representing left and right audio channels. I2S is an electrical serial bus interface used to connect digital audio devices together, and is used to communicate pulse code modulation (PCM) audio data between integrated circuits in an electronic device. The I2S bus separates clock and serial data signals, which results in simpler audio receivers than otherwise required by asynchronous systems that need to recover a clock from a data stream. I2S ports generally require at least three pins, which include a bit clock pin (officially referred to as a continuous serial clock (SCK), and typically called a bit clock (BCLK)), a word clock pin (officially referred to as a word select (WS), and typically called a left-right clock (LRCLK) or frame sync (FS)), and one or more multiplexed serial data pins (officially referred to as serial data (SD), and sometimes called SDATA, SDIN, SDOUT, DACDAT, and/or ADCDAT). Furthermore, in a master mode, an additional pin may be used for a reference clock that is used to generate the word select and bit clocks.

In some cases, however, an audio device such as a soundbar may demand an elevated number of I2S ports. For example, there may be a need to combine (or mix) multiple I2S inputs to one or more time division multiplexing (TDM) channel outputs (e.g., combining and/or mixing four I2S input data lines on one TDM output data line, or combining and/or mixing eight I2S input data lines on two TDM output data lines) to interface multiple I2S audio channels to an audio processor lacking the necessary number of I2S inputs (e.g., because each I2S input requires at least three pins). Furthermore, audio processors generally lack sufficient audio pins and supporting interface to directly handle a large number of I2S inputs due to a pin count, cost, the number of I2S modules that would otherwise be required on-chip, potentially costly redundancy for chips designed for varied applications, and/or challenges associated with different audio sample rates from different audio sources. Although there are existing audio solutions that receive a TDM input and generate multiple I2S outputs, there are limited cost-effective solutions to mix or combine multiple I2S outputs into a TDM chain. Furthermore, although digital-to-analog converters (DACs) and/or analog-to-digital converters (ADCs) may be deployed to facilitate audio mixing (e.g., by first converting digital audio channels to analog, mixing in the analog domain, and then converting the resulting mixed audio to a single ADC digital output), signal integrity of the audio channels will naturally degrade, particularly with analog amplifier noise and sensitivity to other circuit noise injection in the analog domain.

Some aspects described herein relate to a multi-channel audio input mixer that can connect four I2S input ports to a chip equipped with one TDM input port or connect eight I2S input ports to a chip equipped with two TDM inputs, thereby supporting up to eight multiplexed audio channels per TDM port by digital I2S-to-TDM conversion. Assuming that all input ports are associated with the same sample rate, some aspects described herein may enable I2S-to-TDM conversion via a faster bit clock on the TDM port(s) and slower bit clocks on the multiplexed I2S ports. The higher bit clock frequency on the TDM port(s) also factors in the total number of multiplexed channels, sample rate, and/or bits per channel. As described herein, some aspects may implement individual digital sample rate converters for each I2S input port, which affords scalable flexibility and caters to various audio sample rates. Furthermore, as described herein, some aspects described herein may perform sample rate conversion in the digital domain, which negates the need to deploy one or more DACs and/or ADCs to combine or mix multiple digital audio inputs. Accordingly, some aspects described herein provide a multi-channel audio input mixing solution that is cost-effective and scalable on component count, depending on application demands, especially in cases where audio input channels to a receiving audio processor may otherwise lack support for the required number of digital audio interfaces. In this way, some aspects described herein may allow audio processors with fixed designs to service variable market demands that may need to combine a large number of audio input ports over a relatively limited number of TDM channel outputs.

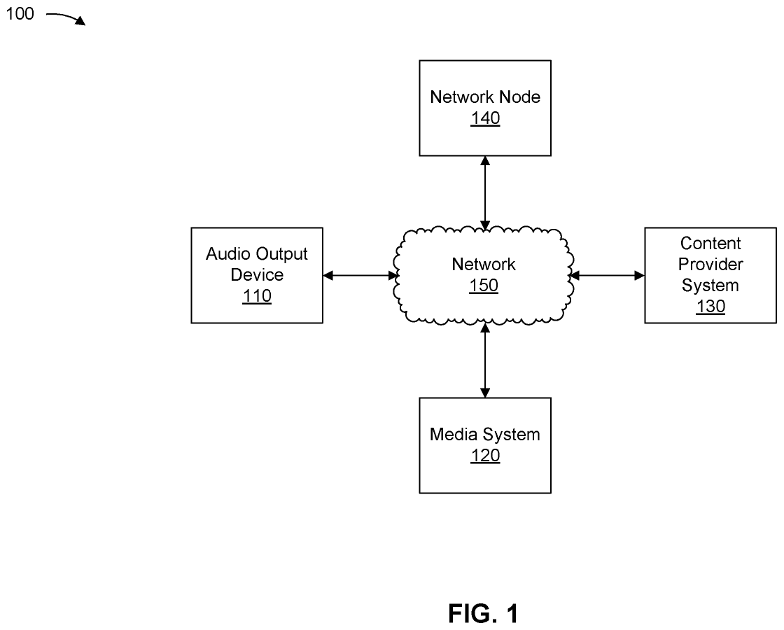

FIG. 1 is a diagram illustrating an example environment 100 in which multiple audio inputs may be converted into a TDM audio data stream, in accordance with the present disclosure. As shown in FIG. 1, the environment 100 may include, for example, an audio output device 110, a media system 120, a content provider system 130, a network node 140, and a network 150. In some aspects, devices of the environment 100 may interconnect via wired connections, wireless connections, or a combination of wired and wireless connections.

The audio output device 110 includes one or more devices capable of receiving, generating, storing, processing, providing, and/or rendering audio content to permit a user to access (e.g., hear) the audio content. For example, the audio output device 110 may include a communication device and/or computing device, such as a television, a soundbar, a stereo receiver, a gaming device, or the like. Additionally, or alternatively, the audio output device 110 may include a mobile device, such as a mobile phone, a laptop computer, a tablet computer, a handheld computer, or the like.

In some aspects, the audio output device 110 may be included within a media system (e.g., a system that includes one or more audio output components and one or more video output components). For example, in some aspects, the audio output device 110 may be included within a home environment (e.g., as a component of a home theater system), a mobile environment (e.g., as a component of a vehicular media system, an infotainment system, a control console, and/or an audio system), and/or a public environment (e.g., as a digital sign, an advertisement device, or the like).

The media system 120 includes one or more devices capable of receiving, transmitting, and/or processing audio content and providing the audio content to a user (e.g., via the audio output device 110). For example, in some aspects, the media platform 120 may include a set-top box, a streaming device, a casting stick (e.g., a high-definition media interface (HDMI) dongle), a computer, a cable card, a gaming device, a portable electronic device, and/or other types of devices capable of receiving, transmitting, and/or processing audio content and providing the audio content to a user. In some aspects, the media system 120 may be included within the audio output device 110 (e.g., similar to a smart television, as an application and/or within a browser of the audio output device 110, or the like). In some aspects, the media system 120 may receive the audio content from the content provider platform 130 via the network 150 and may provide (e.g., forward) the audio content to the audio output device 110 for rendering (e.g., via one or more speakers).

The content provider platform 130 includes one or more devices (e.g., server devices, network devices, or the like) capable of generating, processing, and/or providing audio content to the media system 120 and/or the audio output device 110. For example, the content provider platform 130 may include a multimedia platform that is configured to broadcast, multicast, and/or stream multimedia data associated with the audio content to the media system 120 and/or the audio output device 110, to permit the audio output device 110 to process the multimedia data and render the audio content.

The network node 140 includes one or more devices configured to receive, generate, store, process, and/or provide information related to one or more aspects described herein. For example, the network node 140 may include a base station (a Node B, a gNB, and/or a 5G node B (NB), among other examples), a user equipment (UE), a relay device, a network controller, an access point, a transmission reception point (TRP), an apparatus, a device, a computing system, and/or another suitable processing entity configured to perform one or more aspects described herein. For example, in some aspects, the network node 140 may include an aggregated base station and/or one or more components of a disaggregated base station (e.g., a central unit, a distributed unit, and/or a radio unit) that may communicate with the audio output device 110, the media system 120, and/or the content provider system 130.

The network 150 includes one or more wired and/or wireless networks. For example, the network 150 may include a cellular network (e.g., a Long-Term Evolution (LTE) network, a code division multiple access (CDMA) network, a 3G network, a 4G network, a 5G network, another type of next generation network, and/or the like), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, or the like, and/or a combination of these or other types of networks. In some aspects, the network 150 enables communication among the devices of environment 100.

The number and arrangement of devices shown in FIG. 1 are provided as an example. In practice, there may be additional devices and/or networks, fewer devices and/or networks, different devices and/or networks, or differently arranged devices and/or networks than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

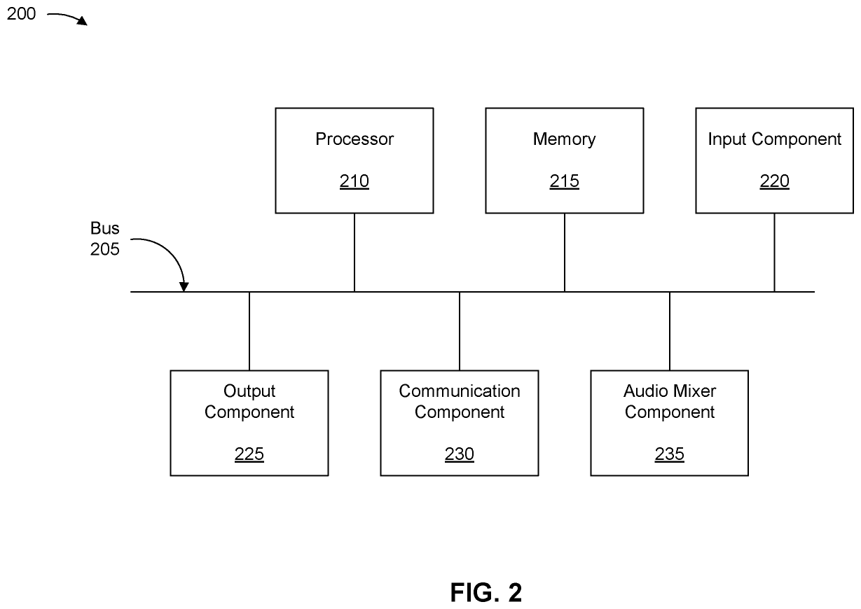

FIG. 2 is a diagram illustrating example components of a device 200, in accordance with the present disclosure. The device 200 may correspond to the audio output device 110, the media system 120, the content provider system 130, and/or the network node 140. In some aspects, the audio output device 110, the media system 120, the content provider system 130, and/or the network node 140 may include one or more devices 200 and/or one or more components of the device 200. As shown in FIG. 2, the device 200 may include a bus 205, a processor 210, a memory 215, an input component 220, an output component 225, a communication component 230, and/or an audio mixer component 235.

The bus 205 may include one or more components that enable wired and/or wireless communication among the components of the device 200. The bus 205 may couple together two or more components of FIG. 2, such as via operative coupling, communicative coupling, electronic coupling, and/or electric coupling. For example, the bus 205 may include an electrical connection (e.g., a wire, a trace, and/or a lead) and/or a wireless bus. The processor 210 may include a central processing unit, a graphics processing unit, a microprocessor, a controller, a microcontroller, a digital signal processor, a field-programmable gate array, an application-specific integrated circuit, and/or another type of processing component. The processor 210 may be implemented in hardware, firmware, or a combination of hardware and software. In some aspects, the processor 210 may include one or more processors capable of being programmed to perform one or more operations or processes described elsewhere herein.

The memory 215 may include volatile and/or nonvolatile memory. For example, the memory 215 may include random access memory (RAM), read only memory (ROM), a hard disk drive, and/or another type of memory (e.g., a flash memory, a magnetic memory, and/or an optical memory). The memory 215 may include internal memory (e.g., RAM, ROM, or a hard disk drive) and/or removable memory (e.g., removable via a universal serial bus connection). The memory 215 may be a non-transitory computer-readable medium. The memory 215 may store information, one or more instructions, and/or software (e.g., one or more software applications) related to the operation of the device 200. In some aspects, the memory 215 may include one or more memories that are coupled (e.g., communicatively coupled) to one or more processors (e.g., processor 210), such as via the bus 205. Communicative coupling between a processor 210 and a memory 215 may enable the processor 210 to read and/or process information stored in the memory 215 and/or to store information in the memory 215.

The input component 220 may enable the device 200 to receive input, such as user input and/or sensed input. For example, the input component 220 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 225 may enable the device 200 to provide output, such as via a display, a speaker, and/or a light-emitting diode. The communication component 230 may enable the device 200 to communicate with other devices via a wired connection and/or a wireless connection. For example, the communication component 230 may include a receiver, a transmitter, a transceiver, a modem, a network interface card, and/or an antenna.

The audio mixer component 235 may connect an audio processor to one or more TDM data chains that each include a plurality of digital sample rate converters; provide, to the plurality of digital sample rate converters in each TDM data chain, a set of TDM clocks that include a sample rate clock input and a bit clock input; connect the plurality of digital sample rate converters in each TDM data chain to a corresponding plurality of audio ports that each correspond to a stereo channel; receive, at the plurality of digital sample rate converters in each TDM data chain, a plurality of digital audio inputs via the plurality of audio ports; receive, at one or more TDM inputs associated with the audio processor, a TDM audio stream from each of the one or more TDM data chains, wherein the TDM audio stream mixes the plurality of digital audio inputs based on the sample rate clock input and the bit clock input; and output the TDM audio stream. Additionally, or alternatively, the audio mixer component 235 may perform one or more other operations described herein.

The device 200 may perform one or more operations or processes described herein. For example, a non-transitory computer-readable medium (e.g., memory 215) may store a set of instructions (e.g., one or more instructions or code) for execution by the processor 210. The processor 210 may execute the set of instructions to perform one or more operations or processes described herein. In some aspects, execution of the set of instructions, by one or more processors 210, causes the one or more processors 210 and/or the device 200 to perform one or more operations or processes described herein. In some aspects, hardwired circuitry may be used instead of or in combination with the instructions to perform one or more operations or processes described herein. Additionally, or alternatively, the processor 210 may be configured to perform one or more operations or processes described herein. Thus, aspects described herein are not limited to any specific combination of hardware circuitry and software.

In some aspects, device 200 may include means for connecting an audio processor to one or more TDM data chains that each include a plurality of digital sample rate converters; means for providing, to the plurality of digital sample rate converters in each TDM data chain, a set of TDM clocks that include a sample rate clock input and a bit clock input; means for connecting the plurality of digital sample rate converters in each TDM data chain to a corresponding plurality of audio ports that each correspond to a stereo channel; means for receiving, at the plurality of digital sample rate converters in each TDM data chain, a plurality of digital audio inputs via the plurality of audio ports; receiving, at one or more TDM inputs associated with the audio processor, a TDM audio stream from each of the one or more TDM data chains, wherein the TDM audio stream mixes the plurality of digital audio inputs based on the sample rate clock input and the bit clock input; and/or means for outputting, by the audio processor, the TDM audio stream. In some aspects, the means for device 200 to perform processes and/or operations described herein may include one or more components of device 200 described in connection with FIG. 2, such as bus 205, processor 210, memory 215, input component 220, output component 225, communication component 230, and/or audio mixer component 235.

The number and arrangement of components shown in FIG. 2 are provided as an example. The device 200 may include additional components, fewer components, different components, or differently arranged components than those shown in FIG. 2. Additionally, or alternatively, a set of components (e.g., one or more components) of the device 200 may perform one or more functions described as being performed by another set of components of the device 200.

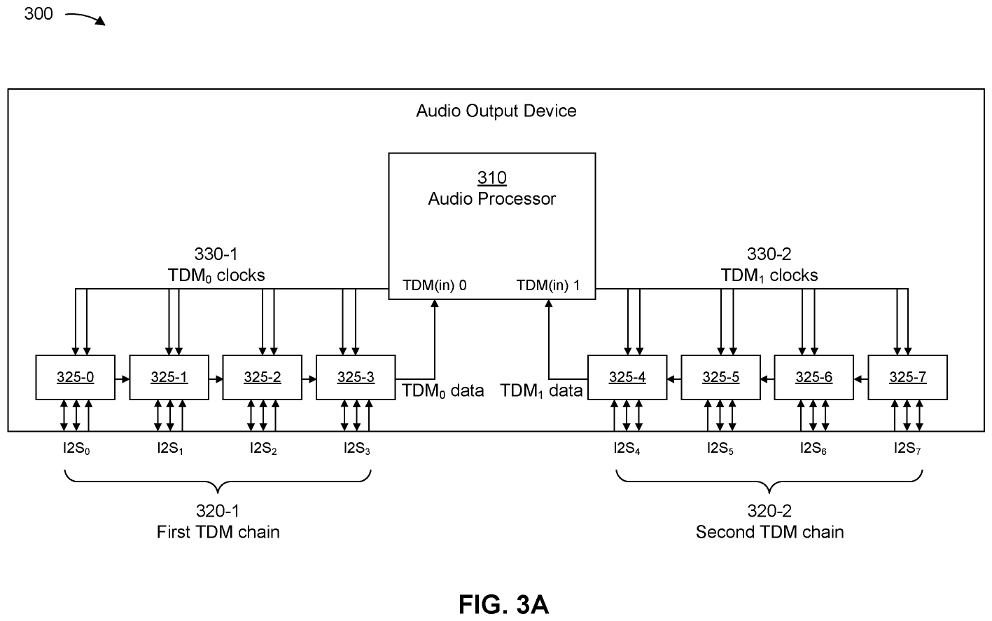

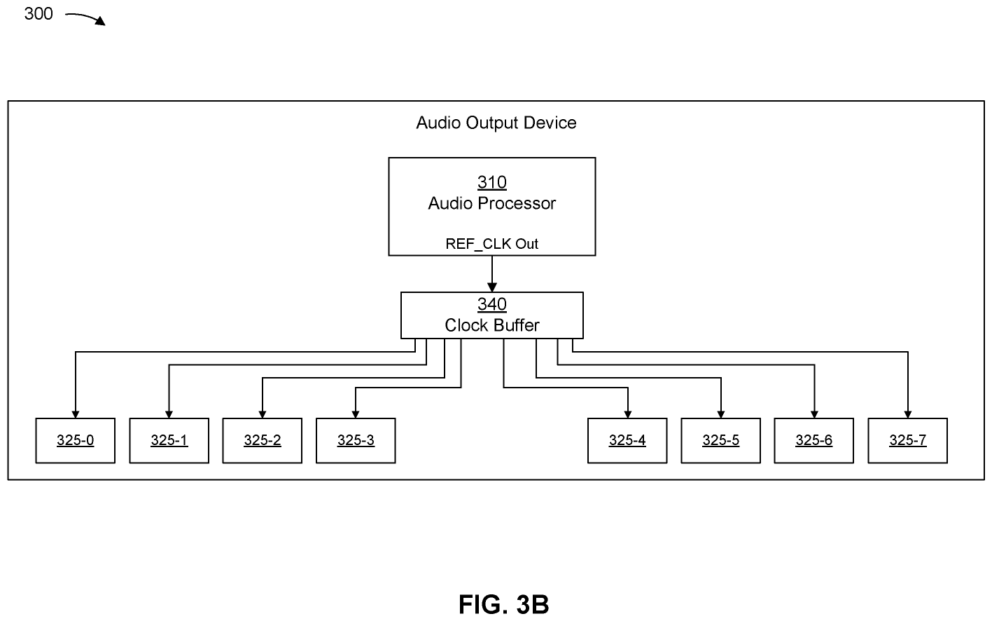

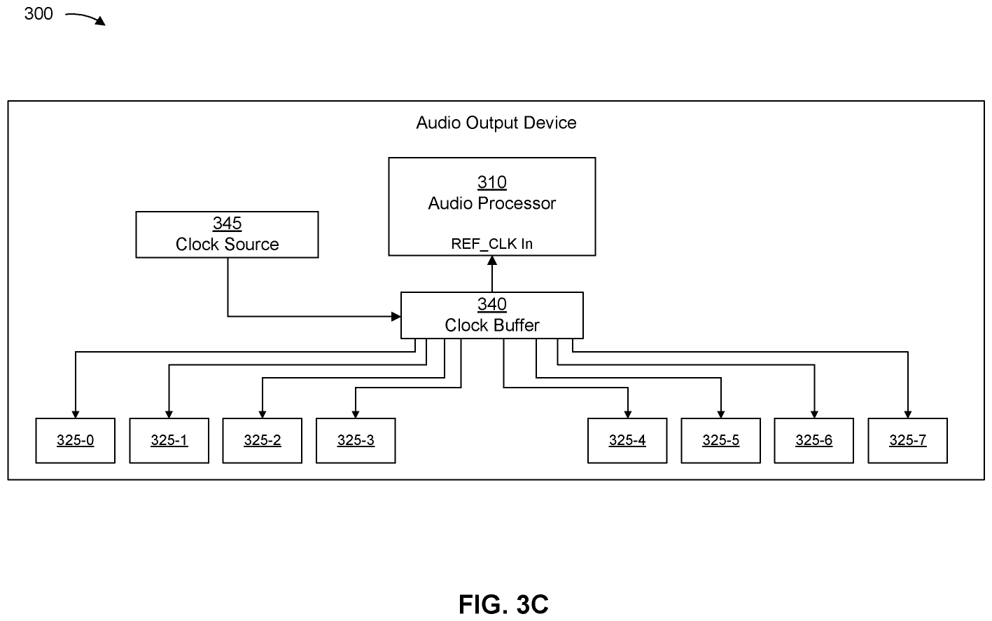

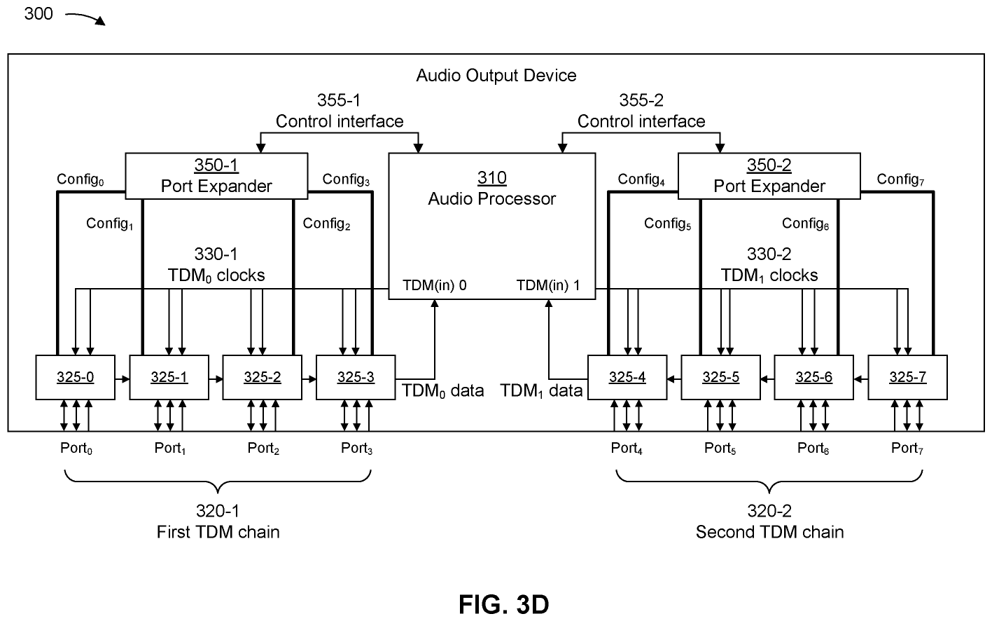

FIGS. 3A-3D are diagrams illustrating examples 300 associated with converting multiple audio inputs into a TDM audio data stream, in accordance with the present disclosure. As shown in FIGS. 3A-3D, examples 300 include an audio output device with an audio processor 310 that may be connected to one or more TDM data chains 320, where each TDM data chain includes a plurality of digital sample rate converters 325. In some aspects, the audio output device may be coupled to one or more other devices, such as a media system, a content provider system, and/or a network node.

As shown in FIG. 3A, the audio processor 310 may be connected to one or more TDM data chains 320 that each include a plurality of digital sample rate converters 325. For example, in FIG. 3A, the audio processor 310 includes a first TDM input (shown as TDM(in) 0) that receives a first TDM input from a first TDM data chain 320-1 that includes a first plurality of digital sample rate converters 325 and a second TDM input (shown as TDM(in) 1) that receives a second TDM input from a second TDM data chain 320-2 that includes a second plurality of digital sample rate converters 325. For example, in FIG. 3A, the first TDM data chain 320-1 includes a first set of four digital sample rate converters 325, shown as digital sample rate converters 325-0, 325-1, 325-2, and 325-3, which correspond to a first set of stereo channels, and the second TDM data chain 320-2 includes a second set of four digital sample rate converters 325, shown as digital sample rate converters 325-4, 325-5, 325-6, and 325-7, which correspond to a second set of stereo channels. Accordingly, FIG. 3A illustrates an example implementation of the audio input device that may support eight stereo I2S input ports that connect to an audio processor 310 equipped with two TDM input ports, thereby supporting up to eight multiplexed audio channels per TDM input port. As shown in FIG. 3A, the audio processor 310 is configured to provide, to the digital sample rate converters 325 in each respective TDM chain 320, a set of TDM clock inputs 330. For example, in some aspects, the set of TDM clock inputs 330 may include, for each digital sample rate converter 325, a sample rate clock input (e.g., corresponding to or equivalent to an LRCLK or left/right clock signal, a frame sync clock signal, or the like) and a bit clock input (e.g., corresponding to a BCLK signal).

In some aspects, in a scenario where the digital sample rate converters 325 operate at the same sample rate for each I2S port and the TDM port(s), conversion from the I2S protocol to a TDM data stream that is conveyed to the audio processor 310 may be achieved by using different clock frequencies for the TDM port(s) and the I2S ports. In particular, when the digital sample rate converters 325 operate at the same sample rate, the bit clock used for the TDM input port associated with the audio processor 310 may be associated with a first clock frequency, and the I2S ports coupled to the various digital sample rate converters 325 may be operated at a second clock frequency that is slower than the first clock frequency to support conversion from the I2S protocol to the TDM data stream. Alternatively, in other cases (e.g., when the digital sample rate converters 325 in a TDM chain operate at different sample rates), the bit clock used for the TDM port(s) may be faster, the same as, or slower than the bit clock on the I2S ports, depending on the application. In some aspects, the bit clock frequency that is used for the TDM ports may have a value that is based on various factors, such as the number of multiplexed audio channels (e.g., corresponding to the number of I2S ports and corresponding digital sample rate converters 325), a sample rate, and/or a number of bits per channel. For example, in some aspects, each TDM chain 320 may share a set of TDM clock inputs (e.g., shown as TDMo clocks 330-1 for the first TDM chain 320-1 and TDMi clocks 330-2 for the second TDM chain 320-2), and the clocks that are shared among the various digital sample rate converters 325 in each TDM chain 320 may be based on the number of multiplexed audio channels, the sample rate, and/or the number of bits per channel, among other examples. For example, in a scenario where there are two TDM chains 320 and the TDM sample rate for a TDM chain 320 is 96 kilohertz (kHz) with 32 bits per channel and four digital sample rate converters 325 per TDM chain 320, the serial (TDM) clock for each TDM chain 320 would be 4×96000×32×2=24.576 megahertz (MHz).

In this case, as shown in FIG. 3A, each digital sample rate converter 325 may include at least three pins that support a single I2S port, which include respective pins for LRCLK, BCLK, and SDATA inputs. In this way, each TDM chain 320 includes a plurality of digital sample rate converters 325, where each digital sample rate converter 325 corresponds to an individual I2S port (e.g., shown in FIG. 3A as I2S₀ through I2S₇, which includes I2S₀ through I2S₃ for the first TDM chain 320-1 and I2S₄ through I2S₇ for the second TDM chain 320-2), which affords scalable flexibility that may cater to various audio sample rates. For example, each digital sample rate converter 325 may be configured to accept one I2S input port and to convert the I2S input port to a TDM output port, which may be deployed in a common TDM data chain 320. Accordingly, in some aspects, the audio output device shown in FIG. 3A includes two TDM data chains 320, with each TDM data chain 320 supporting up to four stereo I2S digital sample rate converters 325, which may provide two TDM data streams that support a total of eight stereo I2S input channels. In this way, the audio output device may support concurrent streaming of two different TDM sample rates, one per TDM data chain 320. Furthermore, in cases where there are different sample rates at the I2S input ports, the multiple independent sample rates at the I2S input ports may be converted to a selected TDM rate separately by each digital sample rate converter 325. Furthermore, in cases where one or more I2S ports are deactivated or absent along a TDM chain 320 and the digital sample rate converters 325 need a running clock to properly execute I2S-to-TDM conversion and thereby generate a valid TDM output stream, an I2S master mode may be deployed for the one or more I2S ports that are deactivated or absent along the TDM chain 320 to supply the running clock that is otherwise absent (e.g., the bit clock, the sample rate clock, and/or the word select clock). Furthermore, in some aspects, the I2S clocks that are coupled to the various digital sample rate converters 325 may be configured as inputs or outputs (e.g., shown by bi-directional arrows), where the direction of the configurable I2S clocks may depend on whether the corresponding digital sample rate converter 325 is configured as a master or a slave with respect to the connected audio output device.

In some aspects, the design shown in FIG. 3A may provide direct support for a reference clock, a bit clock, and a word select clock by using a common distribution technique, where a set of TDM clocks are shared or otherwise distributed among the various digital sample rate converters 325 in each TDM chain. For example, in some aspects, the TDM scheme shown in FIG. 3A may be suitable in certain design conditions, such as a lumped system, the digital sample rate converters 325 being local (e.g., on the same board or circuit) as the audio processor 310, and/or the audio processor 310 being able to provide sufficient drive strength for distributing the shared TDM clock(s) among the various digital sample rate converters 325 in each TDM chain 320. However, in some cases, the audio output device may correspond to a wider distributed system and/or may be subject to adverse operating conditions that pose challenges for simple direct interfacing of different clocks. In such cases, other clock interfacing techniques may be adopted to accommodate board and/or propagation issues, such as the clock buffering techniques shown in FIG. 3B and/or FIG. 3C.

For example, FIGS. 3B-3C illustrate example clock buffering techniques that may be applied for the reference clock that is provided to each digital sample rate converter 325, although the clock buffering techniques shown in FIGS. 3B-3C may be extended to the bit clocks and/or the word select clocks associated with the various digital sample rate converters 325. As shown in FIG. 3B, in a first clock buffering technique, the audio processor 310 may support a reference clock output (shown as REF_CLK Out), which may be provided as an input to a clock buffer 340. In some aspects, the clock buffer 340 may then distribute the reference clock to each digital sample rate converter 325. Additionally, or alternatively, FIG. 3C illustrates a second clock buffering technique that may be applied in a scenario where the audio processor 310 does not include a clock source or otherwise provide a reference clock. In such cases, a separate clock source 345 that is not embedded or otherwise included in the audio processor 310 may generate the reference clock that is input to the clock buffer 340, which routes a buffered output of the reference clock to the audio processor 310 (shown as REF_CLK In) and routes other outputs of the reference clock to the various digital sample rate converters 325.

In some aspects, referring again to FIG. 3A, the digital sample rate converters 325 are generally deployed to support conversion from an I2S interface to a TDM output. Additionally, or alternatively, in some cases, the digital sample rate converters 325 may be configured to support other audio interfaces besides I2S. For example, in some aspects, each digital sample rate converter 325 may be individually configured using one or more pull-up and/or pull-down resistors to passively tailor available configuration options and/or different modes of operation (e.g., associated with different audio interfaces). For example, reset control lines associated with the digital sample rate converters 325 may be directly supported from a general purpose input/output (GPIO) pin of the audio processor 310 by appropriate means, such as driving one or more metal-oxide-semiconductor field-effect transistors (MOSFETs) combined with one or more pull-up resistors in proximity to the reset pins. Additionally, or alternatively, in some aspects, controlled logic may be used to programmatically change configurations for one or more of the digital sample rate converters 325. For example, FIG. 3D illustrates an example where the audio output device includes one or more port expanders 350, such as a first port expander 350-1 for the first TDM chain 320-1 and a second port expander 350-2 for the second TDM chain 320-2. Furthermore, the audio processor 310 may support one or more control interfaces 355, such as a first control interface 355-1 for the first port expander 350-1 associated with the first TDM chain 320-1 and a second control interface 355-2 for the second port expander 350-2 associated with the second TDM chain 320-2. In some aspects, the port expanders 350 and associated control interfaces 355 may be used to achieve programmatic configuration flexibility in cases where the audio output device includes a limited number of GPIO pins, thereby providing the audio output device with independent configuration control for each digital sample rate converter 325. For example, configuration control information may be provided from the audio processor 310 to the port expanders 350 via the associated control interface 355, and configuration control information may then be distributed to the various digital sample rate converters 325 to accommodate various audio formats and diverse deployment scenarios. In such cases, the audio inputs to each digital sample rate converter 325 becomes generic, supporting any suitable audio format (including I2S). For example, as shown in FIG. 3D, the audio inputs for the first TDM chain 320-1 include a first set of audio ports, shown as Port₀ through Port₃, and the audio inputs for the second TDM chain 320-2 include a second set of audio ports, shown as Port₄ through Port₇.

In this way, some aspects described herein may satisfy market demands for audio output devices, such as a soundbar use case that may demand an ability to convert a large number of I2S (or other audio) inputs into a relatively smaller number of TDM audio streams. Furthermore, some aspects described herein may reduce audio pinout requirements for the audio processor 310 that receives the TDM audio streams, and some aspects may preserve audio quality by performing I2S-to-TDM conversion in the digital domain. Furthermore, some aspects may enable extended flexibility by adding supporting control for one or more features of the digital sample rate converters 325, with a possible tradeoff of an increased GPIO pin count. Furthermore, by supporting separate TDM chains 320 that each include a respective plurality of digital sample rate converters 325 that can convert audio inputs from a first format (e.g., I2S) to a TDM audio stream, different TDM chains 320 may generate concurrent TDM audio streams that may run at the same or different sample rates.

As indicated above, FIGS. 3A-3D are provided as examples. Other examples may differ from what is described with respect to FIGS. 3A-3D.

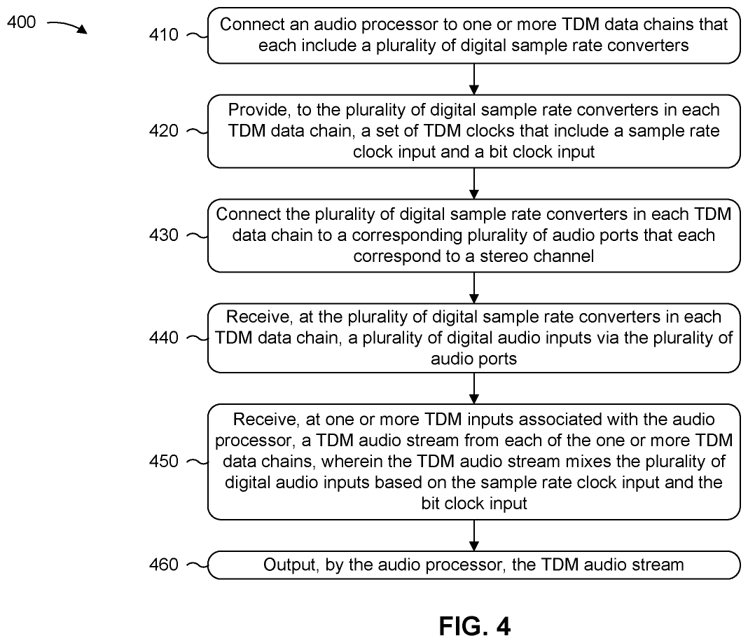

FIG. 4 is a flowchart of an example process 400 associated with a multi-channel audio input mixer, in accordance with the present disclosure. In some aspects, one or more process blocks of FIG. 4 are performed by an audio output device (e.g., audio output device 110, the audio output device shown in FIGS. 3A-3D, or the like). In some aspects, one or more process blocks of FIG. 4 are performed by another device or a group of devices separate from or including the audio output device, such as media system 120, content provider system 130, and/or network node 140. Additionally, or alternatively, one or more process blocks of FIG. 4 may be performed by one or more components of device 200, such as processor 210, memory 215, input component 220, output component 225, communication component 230, and/or audio mixer component 235.

As shown in FIG. 4, process 400 may include connecting an audio processor to one or more TDM data chains that each include a plurality of digital sample rate converters (block 410). For example, the audio processor may connect to one or more TDM data chains that each include a plurality of digital sample rate converters, as described above.

As further shown in FIG. 4, process 400 may include providing, to the plurality of digital sample rate converters in each TDM data chain, a set of TDM clocks that include a sample rate clock input and a bit clock input (block 420). For example, the audio processor may provide, to the plurality of digital sample rate converters in each TDM data chain, a set of TDM clocks that include a sample rate clock input and a bit clock input, as described above.

As further shown in FIG. 4, process 400 may include connecting the plurality of digital sample rate converters in each TDM data chain to a corresponding plurality of audio ports that each correspond to a stereo channel (block 430). For example, the audio processor may connect the plurality of digital sample rate converters in each TDM data chain to a corresponding plurality of audio ports that each correspond to a stereo channel, as described above.

As further shown in FIG. 4, process 400 may include receiving, at the plurality of digital sample rate converters in each TDM data chain, a plurality of digital audio inputs via the plurality of audio ports (block 440). For example, the audio processor may receive, at the plurality of digital sample rate converters in each TDM data chain, a plurality of digital audio inputs via the plurality of audio ports, as described above.

As further shown in FIG. 4, process 400 may include receiving, at one or more TDM inputs associated with the audio processor, a TDM audio stream from each of the one or more TDM data chains, wherein the TDM audio stream mixes the plurality of digital audio inputs based on the sample rate clock input and the bit clock input (block 450). For example, the audio processor may receive, at one or more TDM inputs associated with the audio processor, a TDM audio stream from each of the one or more TDM data chains, wherein the TDM audio stream mixes the plurality of digital audio inputs based on the sample rate clock input and the bit clock input, as described above.

As further shown in FIG. 4, process 400 may include outputting the TDM audio stream (block 460). For example, the audio processor may output the TDM audio stream, as described above.

Process 400 may include additional aspects, such as any single aspect or any combination of aspects described below and/or in connection with one or more other processes described elsewhere herein.

In a first aspect, the plurality of audio ports are associated with an I2S interface.

In a second aspect, alone or in combination with the first aspect, the set of TDM clock inputs is shared among the plurality of digital sample rate converters in each TDM data chain.

In a third aspect, alone or in combination with one or more of the first and second aspects, a frequency of the bit clock input associated with a respective TDM data chain is based on a number of multiplexed audio channels associated with the TDM data chain, a frequency of the sample rate clock input associated with the TDM data chain, and a number of bits per audio channel associated with the TDM data chain.

In a fourth aspect, alone or in combination with one or more of the first through third aspects, the one or more TDM data chains include a first TDM data chain that generates a first TDM audio stream associated with a first TDM sample rate and a second TDM data chain that generates a second TDM audio stream associated with a second TDM sample rate.

In a fifth aspect, alone or in combination with one or more of the first through fourth aspects, process 400 includes operating one or more digital sample rate converters, of the plurality of digital sample rate converters in a TDM data chain, in a master mode based on an absence of a signal associated with a clock input for a corresponding one or more audio ports of the plurality of audio ports.

In a sixth aspect, alone or in combination with one or more of the first through fifth aspects, process 400 includes providing, by the audio processor, a reference clock signal to a clock buffer, and distributing, by the clock buffer, the reference clock signal to the plurality of digital sample rate converters in each TDM data chain.

In a seventh aspect, alone or in combination with one or more of the first through sixth aspects, process 400 includes providing, by a clock source, a reference clock signal to a clock buffer, and providing, by the clock buffer, the reference clock signal to the audio processor and to the plurality of digital sample rate converters in each TDM data chain.

In an eighth aspect, alone or in combination with one or more of the first through seventh aspects, process 400 includes receiving, from the audio processor at one or more port expanders connected to the plurality of digital sample rate converters in each TDM data chain, configuration control information associated with each digital sample rate converter, and configuring each digital sample rate converter independently using the configuration control information received from the audio processor.

Although FIG. 4 shows example blocks of process 400, in some aspects, process 400 includes additional blocks, fewer blocks, different blocks, or differently arranged blocks than those depicted in FIG. 4. Additionally, or alternatively, two or more of the blocks of process 400 may be performed in parallel.

The following provides an overview of some Aspects of the present disclosure:

Aspect 1: A method for mixing multiple audio channels, comprising: connecting an audio processor to one or more TDM data chains that each include a plurality of digital sample rate converters; providing, to the plurality of digital sample rate converters in each TDM data chain, a set of TDM clocks that include a sample rate clock input and a bit clock input; connecting the plurality of digital sample rate converters in each TDM data chain to a corresponding plurality of audio ports that each correspond to a stereo channel; receiving, at the plurality of digital sample rate converters in each TDM data chain, a plurality of digital audio inputs via the plurality of audio ports; receiving, at one or more TDM inputs associated with the audio processor, a TDM audio stream from each of the one or more TDM data chains, wherein the TDM audio stream mixes the plurality of digital audio inputs based on the sample rate clock input and the bit clock input; and outputting, by the audio processor, the TDM audio stream.

Aspect 2: The method of Aspect 1, wherein the plurality of audio ports are associated with an I2S interface.

Aspect 3: The method of any of Aspects 1-2, wherein the set of TDM clock inputs is shared among the plurality of digital sample rate converters in each TDM data chain.

Aspect 4: The method of any of Aspects 1-3, wherein a frequency of the bit clock input associated with a respective TDM data chain is based on a number of multiplexed audio channels associated with the TDM data chain, a frequency of the sample rate clock input associated with the TDM data chain, and a number of bits per audio channel associated with the TDM data chain.

Aspect 5: The method of any of Aspects 1-4, wherein the one or more TDM data chains include a first TDM data chain that generates a first TDM audio stream associated with a first TDM sample rate and a second TDM data chain that generates a second TDM audio stream associated with a second TDM sample rate.

Aspect 6: The method of any of Aspects 1-5, further comprising: operating one or more digital sample rate converters, of the plurality of digital sample rate converters in a TDM data chain, in a master mode based on an absence of a signal associated with a clock input for a corresponding one or more audio ports of the plurality of audio ports.

Aspect 7: The method of any of Aspects 1-6, further comprising: providing, by the audio processor, a reference clock signal to a clock buffer; and distributing, by the clock buffer, the reference clock signal to the plurality of digital sample rate converters in each TDM data chain.

Aspect 8: The method of any of Aspects 1-7, further comprising: providing, by a clock source, a reference clock signal to a clock buffer; and providing, by the clock buffer, the reference clock signal to the audio processor and to the plurality of digital sample rate converters in each TDM data chain.

Aspect 9: The method of any of Aspects 1-8, further comprising: receiving, from the audio processor at one or more port expanders connected to the plurality of digital sample rate converters in each TDM data chain, configuration control information associated with each digital sample rate converter; and configuring each digital sample rate converter independently using the configuration control information received from the audio processor.

Aspect 10: A device for mixing multiple audio channels, comprising: one or more memories; and one or more processors, coupled to the one or more memories, configured to cause the audio processor to: connect an audio processor to one or more TDM data chains that each include a plurality of digital sample rate converters; provide, to the plurality of digital sample rate converters in each TDM data chain, a set of TDM clocks that include a sample rate clock input and a bit clock input; connect the plurality of digital sample rate converters in each TDM data chain to a corresponding plurality of audio ports that each correspond to a stereo channel; receive, at the plurality of digital sample rate converters in each TDM data chain, a plurality of digital audio inputs via the plurality of audio ports; receive, at one or more TDM inputs associated with the audio processor, a TDM audio stream from each of the one or more TDM data chains, wherein the TDM audio stream mixes the plurality of digital audio inputs based on the sample rate clock input and the bit clock input; and output the TDM audio stream.

Aspect 11: The device of Aspect 10, wherein the plurality of audio ports are associated with an I2S interface.

Aspect 12: The device of any of Aspects 10-11, wherein the set of TDM clock inputs is shared among the plurality of digital sample rate converters in each TDM data chain.

Aspect 13: The device of any of Aspects 10-12, wherein a frequency of the bit clock input associated with a respective TDM data chain is based on a number of multiplexed audio channels associated with the TDM data chain, a frequency of the sample rate clock input associated with the TDM data chain, and a number of bits per audio channel associated with the TDM data chain.

Aspect 14: The device of any of Aspects 10-13, wherein the one or more TDM data chains include a first TDM data chain that generates a first TDM audio stream associated with a first TDM sample rate and a second TDM data chain that generates a second TDM audio stream associated with a second TDM sample rate.

Aspect 15: The device of any of Aspects 10-14, wherein the one or more processors are further configured to cause the device to: operate one or more digital sample rate converters, of the plurality of digital sample rate converters in a TDM data chain, in a master mode based on an absence of a signal associated with a clock input for a corresponding one or more audio ports of the plurality of audio ports.

Aspect 16: The device of any of Aspects 10-15, wherein the one or more processors are further configured to cause the device to: provide a reference clock signal to a clock buffer; and distribute the reference clock signal to the plurality of digital sample rate converters in each TDM data chain.

Aspect 17: The device of any of Aspects 10-16, wherein the one or more processors are further configured to cause the device to: provide, by a clock source, a reference clock signal to a clock buffer; and provide, by the clock buffer, the reference clock signal to the audio processor and to the plurality of digital sample rate converters in each TDM data chain.

Aspect 18: The device of any of Aspects 10-17, wherein the one or more processors are further configured to cause the device to: receive, from the audio processor at one or more port expanders connected to the plurality of digital sample rate converters in each TDM data chain, configuration control information associated with each digital sample rate converter; and configure each digital sample rate converter independently using the configuration control information received from the audio processor.

Aspect 19: A non-transitory computer-readable medium storing a set of instructions for wireless communication, the set of instructions comprising: one or more instructions that, when executed by one or more processors of an audio processor, cause the audio processor to: connect an audio processor to one or more TDM data chains that each include a plurality of digital sample rate converters; provide, to the plurality of digital sample rate converters in each TDM data chain, a set of TDM clocks that include a sample rate clock input and a bit clock input; connect the plurality of digital sample rate converters in each TDM data chain to a corresponding plurality of audio ports that each correspond to a stereo channel; receive, at the plurality of digital sample rate converters in each TDM data chain, a plurality of digital audio inputs via the plurality of audio ports; receive, at one or more TDM inputs associated with the audio processor, a TDM audio stream from each of the one or more TDM data chains, wherein the TDM audio stream mixes the plurality of digital audio inputs based on the sample rate clock input and the bit clock input; and output the TDM audio stream.

Aspect 20: The non-transitory computer-readable medium of Aspect 19, wherein the set of TDM clock inputs is shared among the plurality of digital sample rate converters in each TDM data chain.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 1-20.

Aspect 24: A computer program product comprising instructions or code for executing one or more operations recited in one or more of Aspects 1-20.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method for mixing multiple audio channels, comprising:
connecting an audio processor to one or more time division multiplexing (TDM) data chains that each include a plurality of digital sample rate converters;
providing, to the plurality of digital sample rate converters in each TDM data chain, a set of TDM clocks that include a sample rate clock input and a bit clock input;
connecting the plurality of digital sample rate converters in each TDM data chain to a corresponding plurality of audio ports that each correspond to a stereo channel;
receiving, at the plurality of digital sample rate converters in each TDM data chain, a plurality of digital audio inputs via the plurality of audio ports;
receiving, at one or more TDM inputs associated with the audio processor, a TDM audio stream from each of the one or more TDM data chains, wherein the TDM audio stream mixes the plurality of digital audio inputs based on the sample rate clock input and the bit clock input; and
outputting, by the audio processor, the TDM audio stream.

2. The method of claim 1, wherein the plurality of audio ports are associated with an inter-integrated circuit sound (I²S) interface.

3. The method of claim 1, wherein the set of TDM clock inputs is shared among the plurality of digital sample rate converters in each TDM data chain.

4. The method of claim 1, wherein a frequency of the bit clock input associated with a respective TDM data chain is based on a number of multiplexed audio channels associated with the TDM data chain, a frequency of the sample rate clock input associated with the TDM data chain, and a number of bits per audio channel associated with the TDM data chain.

5. The method of claim 1, wherein the one or more TDM data chains include a first TDM data chain that generates a first TDM audio stream associated with a first TDM sample rate and a second TDM data chain that generates a second TDM audio stream associated with a second TDM sample rate.

6. The method of claim 1, further comprising:
operating one or more digital sample rate converters, of the plurality of digital sample rate converters in a TDM data chain, in a master mode based on an absence of a signal associated with a clock input for a corresponding one or more audio ports of the plurality of audio ports.

7. The method of claim 1, further comprising:
providing, by the audio processor, a reference clock signal to a clock buffer; and
distributing, by the clock buffer, the reference clock signal to the plurality of digital sample rate converters in each TDM data chain.

8. The method of claim 1, further comprising:
providing, by a clock source, a reference clock signal to a clock buffer; and
providing, by the clock buffer, the reference clock signal to the audio processor and to the plurality of digital sample rate converters in each TDM data chain.

9. The method of claim 1, further comprising:
receiving, from the audio processor at one or more port expanders connected to the plurality of digital sample rate converters in each TDM data chain, configuration control information associated with each digital sample rate converter; and
configuring each digital sample rate converter independently using the configuration control information received from the audio processor.

10. A device for mixing multiple audio channels, comprising:
one or more memories; and
one or more processors, coupled to the one or more memories, configured to cause the device to:
connect an audio processor to one or more time division multiplexing (TDM) data chains that each include a plurality of digital sample rate converters;
provide, to the plurality of digital sample rate converters in each TDM data chain, a set of TDM clocks that include a sample rate clock input and a bit clock input;
connect the plurality of digital sample rate converters in each TDM data chain to a corresponding plurality of audio ports that each correspond to a stereo channel;
receive, at the plurality of digital sample rate converters in each TDM data chain, a plurality of digital audio inputs via the plurality of audio ports;
receive, at one or more TDM inputs associated with the audio processor, a TDM audio stream from each of the one or more TDM data chains, wherein the TDM audio stream mixes the plurality of digital audio inputs based on the sample rate clock input and the bit clock input; and
output the TDM audio stream.

11. The device of claim 10, wherein the plurality of audio ports are associated with an inter-integrated circuit sound (I2S) interface.

12. The device of claim 10, wherein the set of TDM clock inputs is shared among the plurality of digital sample rate converters in each TDM data chain.

13. The device of claim 10, wherein a frequency of the bit clock input associated with a respective TDM data chain is based on a number of multiplexed audio channels associated with the TDM data chain, a frequency of the sample rate clock input associated with the TDM data chain, and a number of bits per audio channel associated with the TDM data chain.

14. The device of claim 10, wherein the one or more TDM data chains include a first TDM data chain that generates a first TDM audio stream associated with a first TDM sample rate and a second TDM data chain that generates a second TDM audio stream associated with a second TDM sample rate.

15. The device of claim 10, wherein the one or more processors are further configured to cause the device to:
operate one or more digital sample rate converters, of the plurality of digital sample rate converters in a TDM data chain, in a master mode based on an absence of a signal associated with a clock input for a corresponding one or more audio ports of the plurality of audio ports.

16. The device of claim 10, wherein the one or more processors are further configured to cause the device to:
provide a reference clock signal to a clock buffer; and
distribute the reference clock signal to the plurality of digital sample rate converters in each TDM data chain.

17. The device of claim 10, wherein the one or more processors are further configured to cause the device to:
provide, by a clock source, a reference clock signal to a clock buffer; and
provide, by the clock buffer, the reference clock signal to the audio processor and to the plurality of digital sample rate converters in each TDM data chain.

18. The device of claim 10, wherein the one or more processors are further configured to cause the device to:
receive, from the audio processor at one or more port expanders connected to the plurality of digital sample rate converters in each TDM data chain, configuration control information associated with each digital sample rate converter; and
configure each digital sample rate converter independently using the configuration control information received from the audio processor.

19. A non-transitory computer-readable medium storing a set of instructions for wireless communication, the set of instructions comprising:
one or more instructions that, when executed by one or more processors of a device, cause the device to:
connect an audio processor to one or more time division multiplexing (TDM) data chains that each include a plurality of digital sample rate converters;
provide, to the plurality of digital sample rate converters in each TDM data chain, a set of TDM clocks that include a sample rate clock input and a bit clock input;
connect the plurality of digital sample rate converters in each TDM data chain to a corresponding plurality of audio ports that each correspond to a stereo channel;
receive, at the plurality of digital sample rate converters in each TDM data chain, a plurality of digital audio inputs via the plurality of audio ports;
receive, at one or more TDM inputs associated with the audio processor, a TDM audio stream from each of the one or more TDM data chains, wherein the TDM audio stream mixes the plurality of digital audio inputs based on the sample rate clock input and the bit clock input; and
output the TDM audio stream.

20. The non-transitory computer-readable medium of claim 19, wherein the set of TDM clock inputs is shared among the plurality of digital sample rate converters in each TDM data chain.
